(19) United States
(12) Patent Application Publication
(10) Pub. No.: US 2023/0113726 A1
(43) Pub. Date: Apr. 13, 2023

(54) SEMICONDUCTOR PACKAGE

(71) Applicant: SAMSUNG ELECTRONICS CO., LTD., SU (KR)

(72) Inventors: BYOUNGSOO KWAK, HWASEONG-SI (KR); JINWOO PARK, SEOUL (KR)

(21) Appl. No.: 17/872,139

(22) Filed: Jul. 25, 2022

(30) Foreign Application Priority Data
Oct. 13, 2021 (KR) 10-2021-0136157

(51) Int. Cl. H01L 23/31; H01L 25/065; H01L 23/13

(52) U.S. Cl. CPC H01L 23/3135; H01L 23/13; H01L 23/3128; H01L 25/0652; H01L 25/0657; H01L 24/16; H01L 2924/182; H01L 2924/186; H01L 2924/1431; H01L 2924/1436; H01L 2924/1811; H01L 2924/37001

(57) ABSTRACT

A semiconductor package includes an interposer; a first stacked chip including a first semiconductor chip disposed on the interposer and one or more second semiconductor chips disposed on the first semiconductor chip; a first molding layer surrounding the first stacked chip; and a second molding layer surrounding the first molding layer, wherein the second molding layer extends from an uppermost surface of the interposer to a trench of the interposer.

### CROSS-REFERENCE TO RELATED APPLICATION

This application is based on and claims priority under 35 U.S.C. §119 to Korean Patent Application No. 10-2021-0136157, filed on Oct. 13, 2021, in the Korean Intellectual Property Office, the disclosure of which is incorporated by reference herein in its entirety.

### BACKGROUND

The inventive concept relates to a semiconductor package, and more particularly, to a semiconductor package including a plurality of stacked and molded semiconductor chips.

In general, a packaging process is performed on semiconductor chips formed by performing various semiconductor processes on a wafer to form a semiconductor package. The semiconductor package may include a semiconductor chip, an interposer on which the semiconductor chip is mounted, a bonding wire or bump electrically connecting the semiconductor chip to the interposer, and a molding layer for molding the semiconductor chip. Along with the higher integration of semiconductor packages, the reliability and processability of semiconductor packages are currently required to be improved.

### SUMMARY

The inventive concept provides a semiconductor package capable of improving the process yield of a semiconductor process and the reliability of a final semiconductor package.

According to an aspect of the inventive concept, there is provided a semiconductor package that includes an interposer; a first stacked chip including a first semiconductor chip disposed on the interposer and one or more second semiconductor chips disposed on the first semiconductor chip; a first molding layer surrounding the first stacked chip; and a second molding layer surrounding the first molding layer, wherein the second molding layer extends from an uppermost surface of the interposer to a trench of the interposer.

According to another aspect of the inventive concept, there is provided a semiconductor package including an interposer; a first stacked chip including a first semiconductor chip disposed on the interposer and one or more second semiconductor chips disposed on the first semiconductor chip; a third semiconductor chip disposed on the interposer and spaced apart from the first stacked chip in a horizontal direction; a first molding layer surrounding the first stacked chip and the third semiconductor chip; and a second molding layer surrounding the first molding layer, wherein the second molding layer extends from an uppermost surface of the interposer to a trench of the interposer.

According to another aspect of the inventive concept, there is provided a semiconductor package including a package base substrate; an interposer disposed on the package base substrate; a first stacked chip including a first semiconductor chip disposed on the interposer and one or more second semiconductor chips disposed on the first semiconductor chip; a third semiconductor chip disposed on the interposer and horizontally spaced apart from the first stacked chip; a second stacked chip disposed on the interposer, spaced apart from the first stacked chip and the third semiconductor chip in a horizontal direction, and including a fourth semiconductor chip and one or more fifth semiconductor chips disposed on the fourth semiconductor chip; a heat dissipation structure disposed on the first stacked chip, the third semiconductor chip, and the second stacked chip; a first molding layer surrounding a side surface of each of the first stacked chip, the third semiconductor chip, and the second stacked chip; and a second molding layer surrounding a side surface of the first molding layer, wherein a lower surface of the heat dissipation structure is coplanar with or at a higher vertical level than an upper surface of the first stacked chip, an upper surface of the third semiconductor chip, and an upper surface of the second stacked chip, wherein the second molding layer extends from an uppermost surface of the interposer to a trench of the interposer; and wherein a ratio of a height of the trench to a height of the interposer is in a range equal to or less than about 50%.

### BRIEF DESCRIPTION OF THE DRAWINGS

Exemplary embodiments of the inventive concept will be more clearly understood from the following detailed description taken in conjunction with the accompanying drawings in which:

FIG. 1A is a plan view of a semiconductor package according to an exemplary embodiment of the inventive concept, and FIG. 1B is a cross-sectional view illustrating a part I-I′ of the semiconductor package of FIG. 1A;

FIGS. 1C to 1F are cross-sectional views illustrating parts corresponding to I-I′ of FIG. 1A;

FIG. 2 is a cross-sectional view of a semiconductor package according to an exemplary embodiment of the inventive concept;

FIGS. 3A to 3E are diagrams illustrating a method of manufacturing a semiconductor package according to an exemplary embodiment of the inventive concept; and

FIG. 4 is a cross-sectional view of a semiconductor package according to an exemplary embodiment of the inventive concept.

### DETAILED DESCRIPTION OF THE PREFFERED EMBODIMENTS

Hereinafter, exemplary embodiments of the inventive concept will be described in detail with reference to the accompanying drawings. The same reference numerals are used for the same elements in the drawings, and redundant descriptions thereof are omitted.

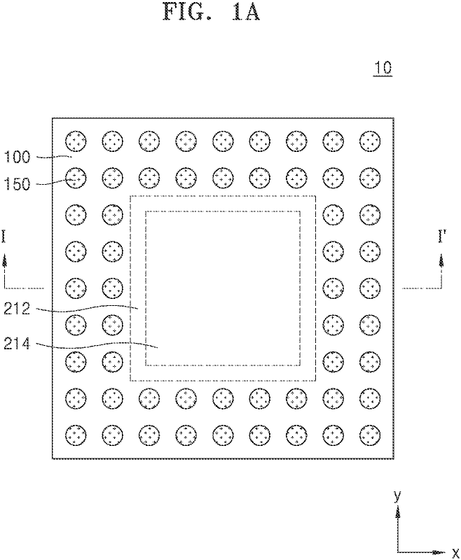

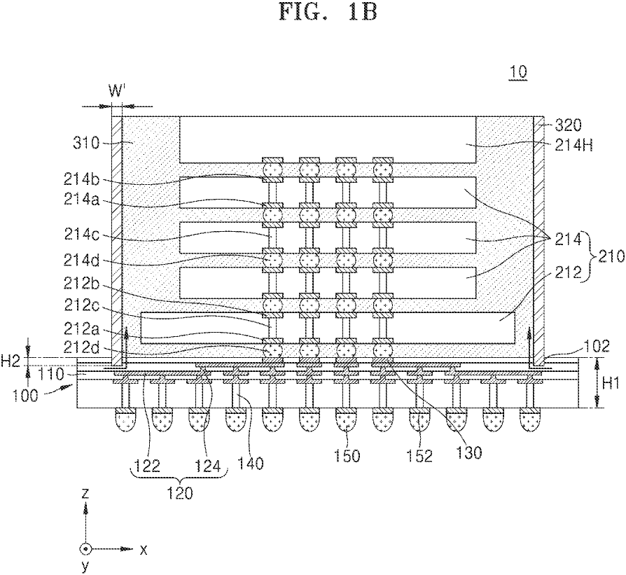

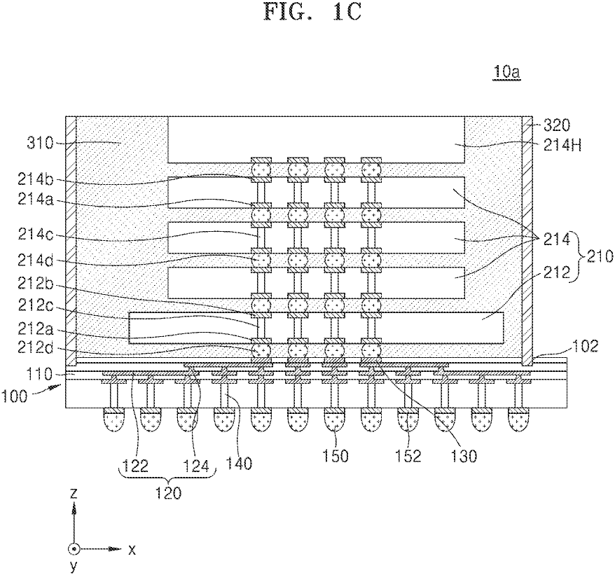

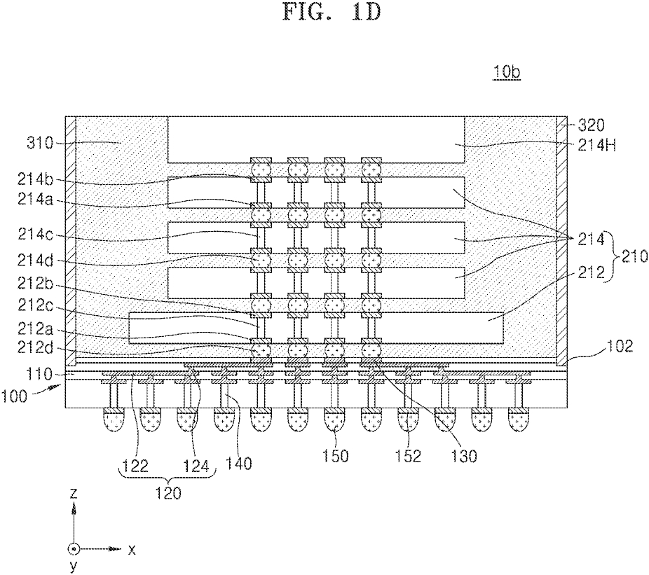

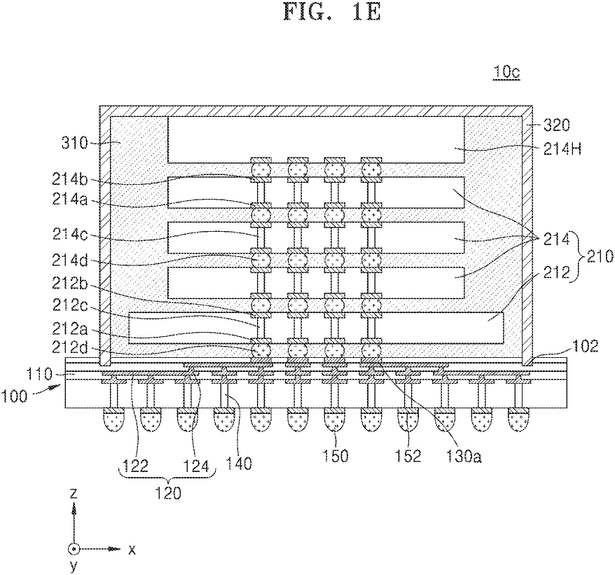

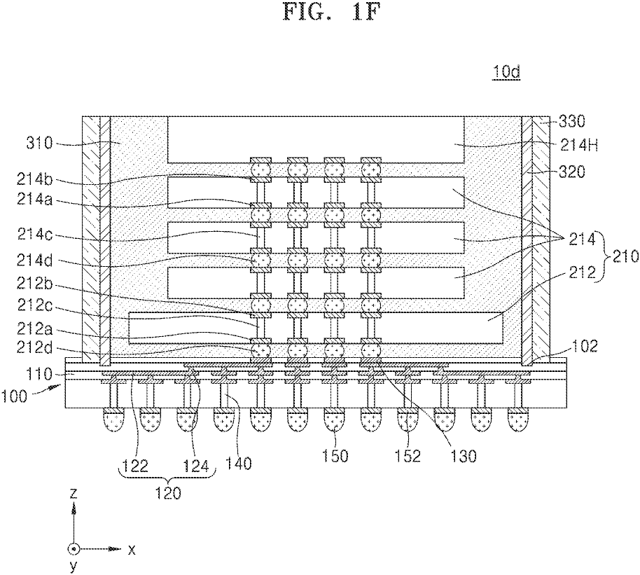

FIG. 1A is a plan view of a semiconductor package 10 according to an exemplary embodiment of the inventive concept, and FIG. 1B is a cross-sectional view illustrating a part I-I′ of the semiconductor package 10 of FIG. 1A.

FIGS. 1C to 1F are cross-sectional views illustrating parts corresponding to I-I′ of FIG. 1A.

Referring to FIGS. 1A to 1F, the semiconductor package 10 of the present embodiment may include an interposer 100, a first stacked chip 210, a first molding layer 310, and a second molding layer 320.

Referring to FIG. 1A, the semiconductor package 10 of the present embodiment may be a fan-out package structure in which a horizontal width and a horizontal area of the interposer 100 have at least greater values than those of a horizontal width and a horizontal area of a footprint configured by the first stacked chip 210. In the fan-out package structure, an external connection terminal 150 may be widely disposed beyond a lower surface of the first stacked chip 210. As described above, when the external connection terminal 150 of the interposer 100 is disposed in a wider part than a space in which a first chip connection terminal 212d of the first semiconductor chip 212 is disposed, the semiconductor package 10 may be the fan-out package structure. In another exemplary embodiment, the semiconductor package 10 of the present exemplary embodiment may be a fan-in package structure in which the horizontal width and the horizontal area of the interposer 100 have values at least equal to or smaller than those of the horizontal width and the horizontal area of the footprint configured by the first stacked chip 210.

In FIGS. 1B to 1F, the semiconductor package 10 includes one first stacked chip 210, and the first stacked chip 210 includes one first semiconductor chip 212 and four second semiconductor chips 214, but this is exemplary, and the number of first stacked chips 210 included in one semiconductor package 10 and the number of first semiconductor chips 212 and second semiconductor chips 214 included in one first stacked chip 210 is not limited thereto.

For example, the semiconductor package 10 may include two or more first stacked chips 210, and one first stacked chip 210 may include three or less second semiconductor chips 214 or five or more second semiconductor chips 214.

In the first stacked chip 210 including the first semiconductor chip 212 and the second semiconductor chips 214, the first semiconductor chip 212 and the second semiconductor chips 214 may be sequentially stacked in a perpendicular direction (Z direction) on the interposer 100. That is, the first semiconductor chip 212 may be stacked on the interposer 100, and the second semiconductor chips 214 may be sequentially stacked on the first semiconductor chip 212.

In the semiconductor package 10 of the present exemplary embodiment, the second molding layer 320 may extend from the uppermost surface of the interposer 100 to a trench 102 of the interposer 100. In addition, the lowermost surface of the second molding layer 320 may contact the interposer 100. Accordingly, the lowermost surface of the second molding layer 320 may be located at a relatively lower vertical level than the uppermost surface of the interposer 100.

The second molding layer 320 may extend to the trench 102 of the interposer 100 so that the semiconductor package 10 may effectively withstand an external impact. Referring to FIG. 1B, an arrow indicates a movement path of the external impact inside the semiconductor package 10. The external impact may include physical and/or chemical agents.

When the uppermost surface of the interposer 100 and the lower surface of the first stacked chip 210, and the lower surface of the first molding layer 310 and/or the lower surface of the second molding layer 320 are substantially coplanar, the interface of the first stacked chip 210, the first molding layer 310, and/or the second molding layer 320 of the semiconductor package 10 may be substantially coplanar. Accordingly, when an impact is applied from the outside of the semiconductor package 10, because the external impact is transmitted through the interface, the semiconductor package 10 may be relatively vulnerable to stress.

In the semiconductor package 10 of the inventive concept, the lowermost surface of the second molding layer 320 may be located at a lower vertical level than the uppermost surface of the interposer 100. That is, the second molding layer 320 may extend into the interposer 100.

Therefore, when an external impact is applied to the semiconductor package 10, the external impact may pass through the lower surface of the second molding layer 320, and then may be transmitted in the direction (Z direction) perpendicular to the interposer 100. Accordingly, the semiconductor package 10 may have relatively high reliability with respect to stress. That is, in the semiconductor package 10, the occurrence of warpage may be reduced.

In some exemplary embodiments, the interposer 100 may be a silicon interposer. The interposer 100 may include an interposer redistribution layer. The interposer redistribution layer may include at least one redistribution insulating layer 110 and a plurality of redistribution patterns 120. The plurality of redistribution patterns 120 may include a plurality of redistribution line patterns 122 and a plurality of redistribution vias 124.

The trench 102 from which a part of the interposer 100 is removed may be disposed in a part of an upper side of the interposer 100. As will be described below, the second molding layer 320 is filled in the trench 102, and thus the reliability of the semiconductor package 10 may be improved.

For example, the interposer redistribution layer may include a plurality of stacked redistribution insulating layers 110. The redistribution insulating layer 110 may include an insulating material, for example, a photo-imageable dielectric (PID) resin, and may further include photosensitive polyimide and/or an inorganic filler.

The plurality of redistribution patterns 120 including the plurality of redistribution line patterns 122 and the plurality of redistribution vias 124 may include, for example, a metal such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), or an alloy thereof, but are not limited thereto.

In some exemplary embodiments, the plurality of redistribution patterns 120 may be formed by stacking a metal or an alloy of the metal on a seed layer including titanium, titanium nitride, and/or titanium tungsten.

The plurality of redistribution line patterns 122 may be disposed on at least one of an upper surface and a lower surface of the redistribution insulating layer 110. The plurality of redistribution vias 124 may pass through at least one redistribution insulating layer to contact and connect to some of the plurality of redistribution line patterns 122, respectively. In some exemplary embodiments, at least some of the plurality of redistribution line patterns 122 may be formed together with some of the plurality of redistribution vias 124 to form an integral body. For example, the redistribution line pattern 122 and the redistribution via 124 in contact with the upper surface of the redistribution line pattern 122 may form an integral body.

The plurality of redistribution patterns 120 including the plurality of redistribution line patterns 122 and the plurality of redistribution vias 124 may be formed by using a plating method. For example, the plurality of redistribution patterns 120 may be formed by using a plating method such as immersion plating, electroless plating, or electroplating.

In some exemplary embodiments, the plurality of redistribution vias 124 may have a tapered shape in which a horizontal width narrows and extends from a lower side to an upper side. That is, the horizontal width of the plurality of redistribution vias 124 may increase as the plurality of redistribution vias 124 move away from the first stacked chip 210.

In another exemplary embodiment, the plurality of redistribution vias 124 may have a tapered shape in which the horizontal width narrows and extends from the upper side to the lower side. That is, the horizontal width of the plurality of redistribution vias 124 may increase as the plurality of redistribution vias 124 move closer to the first stacked chip 210.

Some of the plurality of redistribution line patterns 122 disposed on the upper surface of the interposer redistribution layer and electrically connected to the first chip connection terminal 212d may be referred to as upper surface redistribution pads 130. A first front connection pad 212a of the first semiconductor chip 212 located at the lowest level of the first stacked chip 210 may be connected to the upper surface redistribution pad 130 through the first chip connection terminal 212d.

An external connection pad 152 and the plurality of redistribution patterns 120 may be electrically connected to each other through an interposer through electrode 140. The interposer through electrodes 140 may pass through the inside of the interposer 100. The interposer through electrodes 140 may transmit electrical signals by connecting the upper surface redistribution pad 130 and the external connection pad 152 with electrodes inside the interposer 100.

The external connection pad 152 may be attached to the lower surface of the interposer 100. A package connection terminal 150 may be attached to the external connection pad 152. The package connection terminal 150 may function as an external connection terminal of the semiconductor package 10. The package connection terminal 150 may electrically connect the semiconductor package 10 to the outside of the semiconductor package 10. In some exemplary embodiments, the package connection terminal 150 may include a conductive bump formed of a conductive material, for example, a metal material including at least one of tin (Sn), silver (Ag), copper (Cu), and aluminum (Al) and/or a solder ball, etc.

The external connection pad 152 may be disposed on a part corresponding to the lower surface of the first semiconductor chip 212 located at the lowest vertical level of the first stacked chip 210 and a part extending outwardly in a first horizontal direction (X direction) and a second horizontal direction (Y direction) on the lower surface of the first semiconductor chip 212. As a result, the interposer 100 may function to rearrange the first front connection pad 212a of the first semiconductor chip 212 as the external connection pad 152 on a part which is wider than the lower surface of the first semiconductor chip 212 located at the lowest vertical level of the first stacked chip 210.

In another exemplary embodiment, the interposer 100 may be redistribution layer (RDL) interposer. The RDL interposer may include an interposer redistribution layer. The interposer redistribution layer may include at least one redistribution insulating layer 110 and the plurality of redistribution patterns 120. The plurality of redistribution patterns 120 may include the plurality of redistribution line patterns 122 and the plurality of redistribution vias 124.

The RDL interposer may omit the upper surface redistribution pad 130 and/or the interposer through electrode 140.

According to an exemplary embodiment of the inventive concept, the interposer 100 may be replaced with a semiconductor substrate. The semiconductor substrate may include silicon (Si). However, the inventive concept is not limited thereto, and the semiconductor substrate may include a semiconductor element such as germanium (Ge), or a compound semiconductor such as silicon carbide (SiC), gallium arsenide (GaAs), indium arsenide (InAs), and indium phosphide (InP).

The first stacked chip 210 may include the first semiconductor chip 212 disposed on the interposer 100 and one or more second semiconductor chips 214 disposed on the first semiconductor chip 212. As described above, the first stacked chip 210 may include two or more second semiconductor chips 214. For example, the first stacked chip 210 may include four, eight, or twelve second semiconductor chips 214. The first semiconductor chip 212 and the second semiconductor chip 214 may be sequentially stacked in the vertical direction (Z direction).

For example, the first semiconductor chip 212 and/or the second semiconductor chip 214 may be a memory cell chip. For example, the first semiconductor chip 212 and/or the second semiconductor chip 214 may be a volatile memory such as a dynamic random access memory (DRAM), a static random access memory (SRAM), etc., or a nonvolatile memory such as a phase-change random access memory (PRAM), a magneto-resistive random access memory (MRAM), a ferroelectric random access memory (FeRAM), or a resistive random access memory (RRAM).

In some exemplary embodiments, the first semiconductor chip 212 may not include a memory cell. The first semiconductor chip 212 may include a test logic circuit such as serial-parallel conversion circuit, a design for test (DFT), the Joint Test Action Group (JTAG), a memory built-in self-test (MBIST), etc. and a signal interface circuit such as a PHY. Meanwhile, the second semiconductor chip 214 may include a memory cell. For example, the first semiconductor chip 212 may be a buffer chip controlling the second semiconductor chip 214.

In another exemplary embodiment, the first semiconductor chip 212 may be a logic chip. For example, the first semiconductor chip 212 may be, an application processor (AP), a micro-processor, a central processing unit (CPU), a controller, a graphic processor unit (GPU), or an application specific integrated circuit (ASIC), etc.

In some exemplary embodiments, the first semiconductor chip 212 and the plurality of second semiconductor chips 214 may constitute a high bandwidth memory (HBM). In some exemplary embodiments, the first semiconductor chip 212 may be a buffer chip controlling a HBM DRAM, and the second semiconductor chip 214 may be a memory cell chip having cells of the HBM DRAM controlled by the first semiconductor chip 212. The second semiconductor chip 214 may include a plurality of semiconductor chips. The first semiconductor chip 212 may be referred to as a buffer chip, a master chip, or an HBM controller die, and the plurality of second semiconductor chips 214 may be referred to as a memory chip, a slave chip, a DRAM dice), or a DRAM slice. The first semiconductor chip 212 and the plurality of second semiconductor chips 214 stacked on the first semiconductor chip 212 may be collectively referred to as an HBM DRAM device.

The first semiconductor chip 212 may include a first substrate, the plurality of first front connection pads 212a, a plurality of first rear connection pads 212b, and a plurality of first through electrodes 212c. The second semiconductor chip 214 may include a second substrate, a plurality of second front connection pads 214a, a plurality of second rear connection pads 214b, and a plurality of second through electrodes 214c.

The first substrate and the second substrate may include silicon (Si). Alternatively, the first substrate and the second substrate may include a semiconductor element such as germanium (Ge), or a compound semiconductor such as silicon carbide (SiC), gallium arsenide (GaAs), indium arsenide (InAs), and indium phosphide (InP). The first substrate and the second substrate may have an active surface and an inactive surface opposite to the active surface.

The first substrate and the second substrate may include various types of a plurality of individual devices on the active surface. The plurality of individual devices may include various microelectronic devices, for example, a metal-oxide-semiconductor field effect transistor (MOSFET) such as a complementary metal-insulator-semiconductor transistor (CMOS), a system large scale integration (LSI), an image sensor such as a CMOS imaging sensor (CIS), a micro-electro-mechanical system (MEMS), an active device and/or a passive device, etc.

The semiconductor substrate may be a printed circuit board (PCB) including a plurality of package substrate pads. However, the semiconductor substrate is not limited to the structure and material of the PCB, and may include various types of substrates.

The first and second semiconductor chips 212 and 214 may respectively include first and second semiconductor devices configured by the plurality of individual devices.

The first and second semiconductor devices may be respectively formed on the active surfaces of the first and second substrates, and the plurality of first and second front connection pads 212a and 214a and the plurality of first and second rear connection pads 212b may be respectively disposed on the active surfaces and the inactive surfaces of the first and second substrates.

The plurality of first through electrodes 212c may vertically penetrate at least a part of the first substrate to electrically connect the plurality of first front connection pads 212a and the plurality of first rear connection pads 212b.

The plurality of second through electrodes 214c may vertically penetrate at least a part of the second substrate to electrically connect the plurality of second front connection pads 214a and the plurality of first rear connection pads 212b. The plurality of second through electrodes 214c may be electrically connected to the plurality of first through electrodes 212c.

The first and second through electrodes 212c and 214c may be through silicon vias (TSVs) penetrating silicon of the semiconductor chips 212 and 214. The TSVs may transmit electrical signals by connecting the inside of the semiconductor chips 212 and 214 with electrodes through micro holes in the semiconductor chips 212 and 214.

In FIGS. 1B to 1F, the semiconductor chips 212 and 214 include the four through electrodes 212c and 214c, respectively, but this is exemplary and the number of the through electrodes 212c and 214c respectively included in the semiconductor chips 212 and 214 is not limited thereto.

The plurality of first front connection pads 212a of the first semiconductor chip 212 may be electrically connected to the plurality of upper surface redistribution pads 130 respectively through the first chip connection terminal 212d.

A plurality of first chip connection terminals 212d may be respectively attached onto the plurality of first front connection pads 212a of the first semiconductor chip 212. A plurality of second chip connection terminals 214d may be respectively attached onto the plurality of second front connection pads 214a of the second semiconductor chip 224.

The first chip connection terminals 212d may be interposed between the upper surface redistribution pad 130 of the interposer 100 and the plurality of first front connection pads 212a of the first semiconductor chip 212 to electrically connect the interposer 100 and the first semiconductor chip 212.

The second chip connection terminals 214d may be disposed between the plurality of first rear connection pads 212b of the first semiconductor chip 212 and the plurality of second front connection pads 214a of the second semiconductor chip 214. In addition, the second chip connection terminals 214d may be interposed between the plurality of second front connection pads 214a and the second rear connection pads 214b of the second semiconductor chip 214 to electrically connect the first semiconductor chip 212 and/or the second semiconductor chips 214.

As a result, the first semiconductor chip 212 and the plurality of second semiconductor chips 214 may be electrically connected to each other.

According to another exemplary embodiment, the first semiconductor chip 212 and the second semiconductor chip 214 at the lowermost end among the plurality of second semiconductor chips 214 may be connected to each other through Cu-to-Cu direct bonding, oxide bonding and/or direct contact of bonding pads through copper.

In some exemplary embodiments, a second semiconductor chip 214H located at the uppermost end among the plurality of second semiconductor chips 214 and disposed farthest from the first semiconductor chip 212 may omit the second rear connection pad 214b and the second semiconductor electrode 214c.

For example, the thickness of the second semiconductor chip 214H located at the uppermost end may be greater than the thickness of each of the other second semiconductor chips 214.

The chip connection terminals 212d and 214d may be respectively attached to the semiconductor chips 212 and 214 after an under bump metallization (UBM) layer is formed on the semiconductor chips 212 and 214 by vacuum or electroplating. The UBM layer may facilitate adhesion between the semiconductor chips 212 and 214 and the chip connection terminals 212d and 214d.

An insulating adhesive layer may be interposed between the first semiconductor chip 212 and the second semiconductor chip 214 and/or between the plurality of second semiconductor chips 214. The insulating adhesive layer may be attached to the lower surface of each of the plurality of second semiconductor chips 214 to attach each of the plurality of second semiconductor chips 214 onto a lower structure, for example, the first semiconductor chip 212 or the other second semiconductor chips 214 located at a lower side among the second semiconductor chips 214.

The insulating adhesive layer may include a non-conductive film (NCF), a non-conductive paste (NCP), an insulating polymer, or an epoxy resin.

The insulating adhesive layer may surround the first and second chip connection terminals 212d and 214d and may fill spaces between the first semiconductor chip 212 and the plurality of second semiconductor chips 214.

The semiconductor package 10 may further include the first molding layer 310 and the second molding layer 320 surrounding the first stacked chip 210 on the interposer 100. The first molding layer 310 and the second molding layer 320 may be formed of, for example, epoxy mold compound (EMC).

The first molding layer 310 and the second molding layer 320 may directly contact each other. That is, an outer surface of the first molding layer 310 and an inner surface of the second molding layer 320 may contact each other. This may be configured such that external stress proceeds along the interface between the first molding layer 310 and the second molding layer 320.

In addition, the second molding layer 320 may surround the outer surface of the first molding layer 310 to physically protect the first molding layer 310.

The first molding layer 310 and the second molding layer 320 may be formed of the same material or different materials.

When the first molding layer 310 and the second molding layer 320 are formed of different materials, warpage generation of the semiconductor package 10 may be suppressed.

In another exemplary embodiment, the first molding layer 310 may include at least one of a silicon (Si)-based material, a thermosetting material, a thermoplastic material, and a UV treatment material. The second molding layer 320 may include at least one of an epoxy-based material, a thermosetting material, a thermoplastic material, and a UV treatment material.

For example, the thermosetting material may include at least one curing agent of a phenol type, an acid anhydride type, and an amine type and an additive of acrylic polymer.

The first molding layer 310 may surround the upper surface of the interposer 100 and the first stacked chip 210. The second molding layer 320 may cover a side surface of the first molding layer 310 and/or an upper surface of the first molding layer 310.

When the second molding layer 320 covers only the side surface of the first molding layer 310, the upper surface of the first stacked chip 210, the upper surface of the first molding layer 310, and the upper surface of the second molding layer 320 may be substantially coplanar.

In addition, a width W′ in the first horizontal direction (X direction) from the inner surface of the second molding layer 320 to the outer surface of the second molding layer 320 may be equal to or less than about 100 µm.

In some other exemplary embodiments, when both the first semiconductor chip 212 and the second semiconductor chip 214 do not cover the upper surface of the interposer 100, the first molding layer 310 and the second molding layer 320 may further cover a part of the upper surface of the interposer 100 that is not covered by the first semiconductor chip 212 and the second semiconductor chip 214.

Referring to the semiconductor package 10 of FIG. 1B, each of the outer surfaces of the second molding layer 320 may not be aligned with the side surface of the interposer 100 in the vertical direction, and may be located inside the interposer 100 in the first and second horizontal directions (X direction and Y direction).

Referring to the semiconductor package 10a of FIG. 1C, one of the outer surfaces of the second molding layer 320 may be substantially coplanar with the side surface of the interposer 100, and the other outer surfaces of the second molding layer 320 may not be aligned with the side surface of the interposer 100 in the vertical direction (Z direction), and may be located inside the interposer 100 in the first and second horizontal directions (X direction and Y direction).

Referring to the semiconductor package 10b of FIG. 1D, each of the outer surfaces of the second molding layer 320 may be coplanar with the side surface of the interposer 100.

Referring to the semiconductor package 10c of FIG. 1E, the second molding layer 320 may cover the upper surface of the first molding layer 310. Accordingly, the highest surface in the lower surface of the second molding layer 320 may be substantially coplanar with the upper surface of the first stacked chip 210 and the upper surface of the first molding layer 310.

Referring to the semiconductor package 10d of FIG. 1F, the semiconductor package 10 of the present exemplary embodiment may include the third molding layer 330 covering the side surface of the second molding layer 320 on the interposer 100. The third molding layer 330 may include a plurality of layers. The third molding layer 330 may be formed of the same material as or different materials from the first molding layer 310 and the second molding layer 320.

For example, a lower surface of the third molding layer 330 may be substantially coplanar with the upper surface of the interposer 100 and the upper surface of the first molding layer 310.

As a further example, the lower surface of the third molding layer 330 may be located at a different vertical level from the lower surface of the first molding layer 310.

As described above, the second molding layer 320 may extend from the uppermost surface of the interposer 100 to the trench 102 of the interposer 100, and the lowermost surface of the second molding layer 320 may contact the interposer 100. Accordingly, the lowermost surface of the second molding layer 320 may be located at a relatively lower vertical level than the uppermost surface of the interposer 100.

The ratio of a height H2 of the trench 102 of the interposer 100 to a height H1 of the interposer 100 in the vertical direction (Z direction) may be in the range equal to or less than about 50%. When the ratio of the height H2 from the uppermost surface of the interposer 100 to the lowermost surface of the second molding layer 320 to the height H1 of the interposer 100 in the vertical direction (Z direction) is in the range equal to or less than about 50%, the interposer 100 may have higher resiliency to external stress.

According to another exemplary embodiment of the inventive concept, the range of the height H2 of the trench 102 from the uppermost surface of the interposer 100 may be equal to or less than about 50 µm.

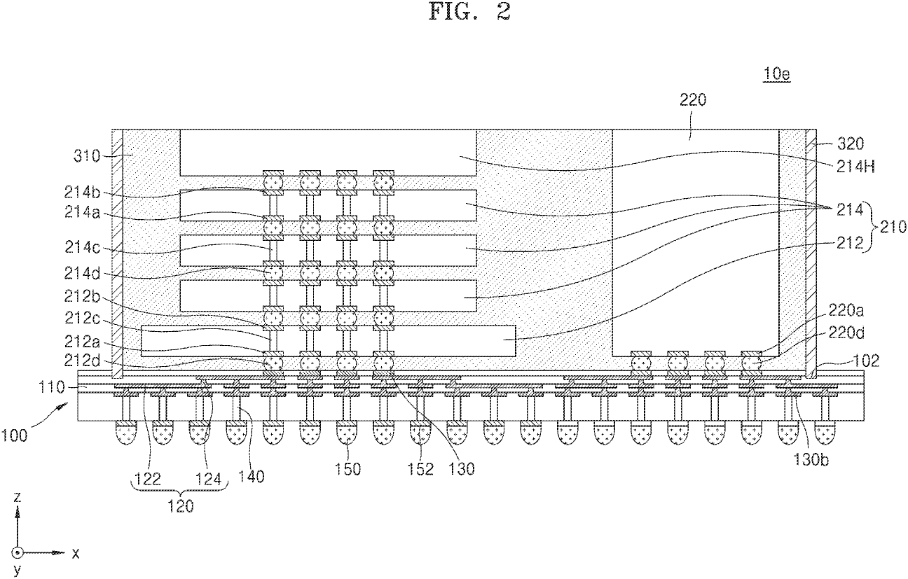

FIG. 2 is a cross-sectional view of a semiconductor package 10e including the first stacked chip 210 and a third semiconductor chip 220 according to an exemplary embodiment of the inventive concept. The same reference numerals as those of FIGS. 1A to 1F denote substantially the same components, and descriptions that are redundant with respect to those given with reference to FIGS. 1A to 1F are be omitted.

Referring to FIG. 2, the semiconductor package 10e may include the first to third semiconductor chips 212, 214, and 220 including a system in package structure. The second semiconductor chip 214 may include a memory cell chip, and the third semiconductor chip 220 may include a logic chip.

The third semiconductor chip 220 may be spaced apart from the first stacked chip 210 in the first horizontal direction (X direction) on the interposer 100.

The third semiconductor chip 220 includes a third substrate and a plurality of third front connection pads 220a.

The third substrate, a first substrate, and a second substrate may be substantially the same.

The third semiconductor chip 220 may include a third semiconductor device configured by a plurality of individual devices. For example, the third semiconductor chip 220 may be an application processor (AP), a micro-processor, a central processing unit (CPU), a controller, a graphic processor unit (GPU), or an application specific integrated circuit (ASIC).

A plurality of third chip connection terminals 220d may be attached onto the plurality of third front connection pads 220a of the third semiconductor chip 220.

The third chip connection terminal 220d may be interposed between the upper surface redistribution pad 130 of the interposer 100 and the plurality of third front connection pads 220a of the third semiconductor chip 220 to electrically connect the interposer 100 and the third semiconductor chip 220.

The first molding layer 310 may surround an upper surface of the interposer 100, a side surface of the first stacked chip 210, and a side surface of the third semiconductor chip 220.

As described above, the second molding layer 320 may extend from the upper surface of the interposer 100 to the trench 102 of the interposer 100, and the lowermost surface of the second molding layer 320 may contact the interposer 100. Accordingly, the lowermost surface of the second molding layer 320 may be located at a relatively lower vertical level than the upper surface of the interposer 100.

In FIG. 2, it is illustrated that the second molding layer 320 surrounds only the side surface of the first molding layer 310 by way of example, but similarly to that shown in FIG. 1E, the second molding layer 320 may also surround the upper surface of the first molding layer 310, the upper surface of the first stacked chip 210 and the upper surface of the third semiconductor chip 220.

The ratio of the height H2 of the trench 102 of the interposer 100 to the height H1 of the interposer 100 in the vertical direction (Z direction) may be in the range equal to or less than about 50%. When the ratio of the height H2 from the uppermost surface of the interposer 100 to the lowermost surface of the second molding layer 320 to the height H1 of the interposer 100 in the vertical direction (Z direction) is in the range equal to or less than 50%, the interposer 100 may have higher resiliency to external stress.

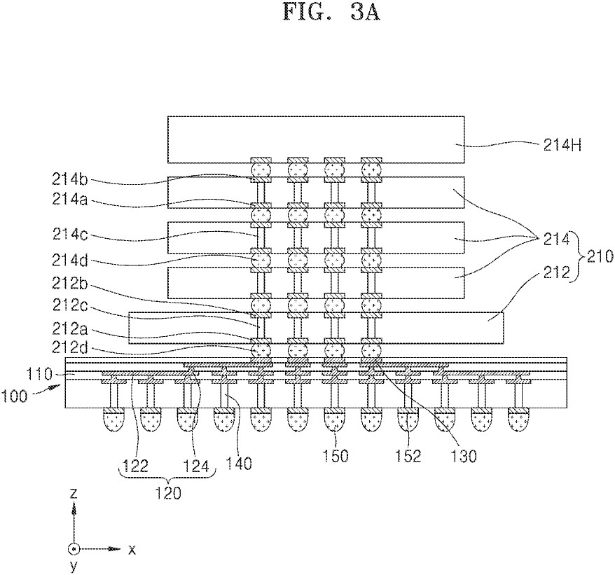

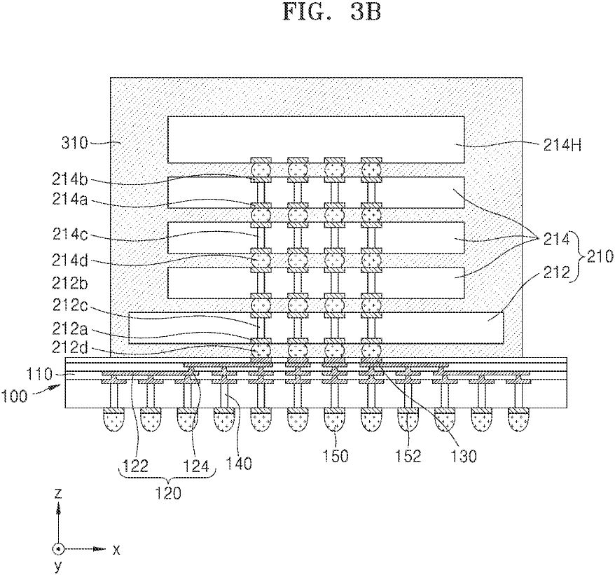

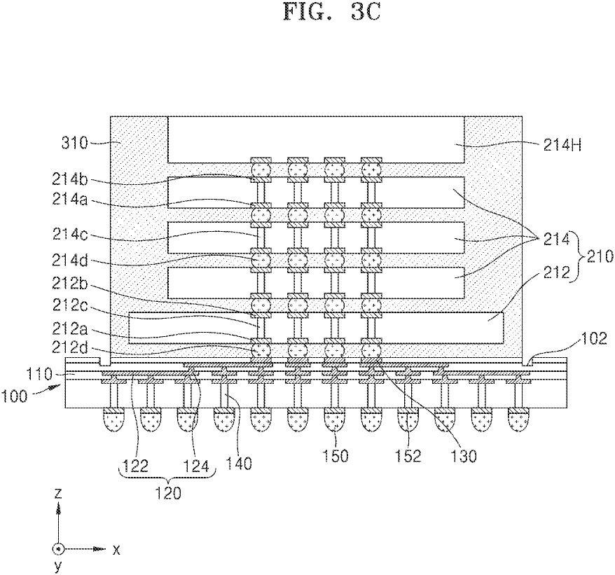

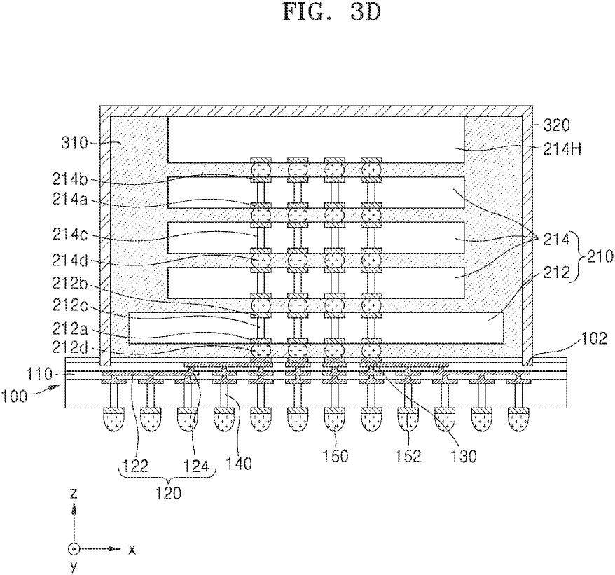

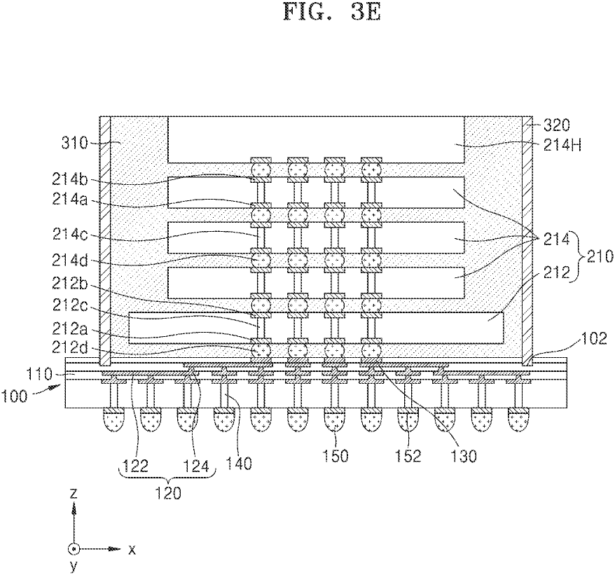

FIGS. 3A to 3E are diagrams illustrating a method of manufacturing the semiconductor package 10 according to an exemplary embodiment of the inventive concept. FIGS. 3A to 3E are diagrams illustrating the method of manufacturing the semiconductor package 10 shown in FIG. 1B.

For convenience, in FIGS. 3A to 3E, one first stacked chip 210 is disposed on one interposer 100, but the number of the first stacked chips 210 disposed on one interposer 100 is not limited thereto when the semiconductor package 10 is manufactured.

Referring to FIG. 3A, the first stacked chip 210 may be mounted on the interposer 100. In FIG. 3A, it is illustrated that the semiconductor package 10 is manufactured using a chip-last method of first forming the interposer 100 and then mounting the first stacked chip 210 on the interposer 100 by way of example, but the semiconductor package 10 may also be manufactured using a chip-first method of first disposing the first stacked chip 210 and then forming the interposer 100.

Referring to FIG. 3B, the semiconductor package 10 may include the first molding layer 310 surrounding an upper surface of the interposer 100 and side and upper surfaces of the first stacked chip 210. The first molding layer 310 may include at least one of a silicon (Si)-based material, a thermosetting material, a thermoplastic material, and a UV treatment material.

Referring to FIG. 3C, an upper part of the first molding layer 310 mounted on the interposer 100 may be ground and removed. Also, an upper part of the interposer 100 may be removed. The removed part of the interposer 100 may be referred to as the trench 102. The trench 102 may be filled with the second molding layer 320 afterwards.

The upper surface of the first molding layer 310 which has been partially ground and removed may be located at substantially the same vertical level as the upper surface of the first stacked chip 210.

Referring to FIG. 3D, the second molding layer 320 may be formed on the upper and side surfaces of the interposer 100 and the first molding layer 310. The second molding layer 320 may surround the side surface of the first molding layer 310 and/or the upper surface of the first molding layer 310. In addition, the lowermost surface of the second molding layer 320 may be located at a lower vertical level than the uppermost surface of the interposer 100. That is, the second molding layer 320 may be filled in the trench 102 of the interposer 100.

The second molding layer 320 may include at least one of an epoxy-based material, a thermosetting material, a thermoplastic material, and a UV treatment material.

For example, the thermosetting material may include at least one curing agent of a phenol type, an acid anhydride type, and an amine type and an additive of acrylic polymer.

The first molding layer 310 and the second molding layer 320 may be formed of the same or different materials. When the first molding layer 310 and the second molding layer 320 are formed of different materials, warpage generation of the semiconductor package 10 may be suppressed.

Referring to FIG. 3E, the semiconductor package 10 of FIG. 1B may be formed by grinding an upper part of the second molding layer 320 and then sawing in individual package units. The sawing may refer to a process of manufacturing individual package units such that an arbitrary number of first stacked chips 210 are disposed on the interposer 100.

The upper surface of the second molding layer 320 may be substantially coplanar with the upper surface of the first stacked chip 210 and the upper surface of the first molding layer 310.

In FIG. 3E, it is illustrated that the second molding layer 320 surrounds the side surface of the first molding layer 310 and the upper surface of the first molding layer 310 by way of example, but the second molding layer 320 may also surround only the side surface of the first molding layer 310.

In addition, the semiconductor package 10 may further include one or more third molding layers 330 surrounding the second molding layer 320.

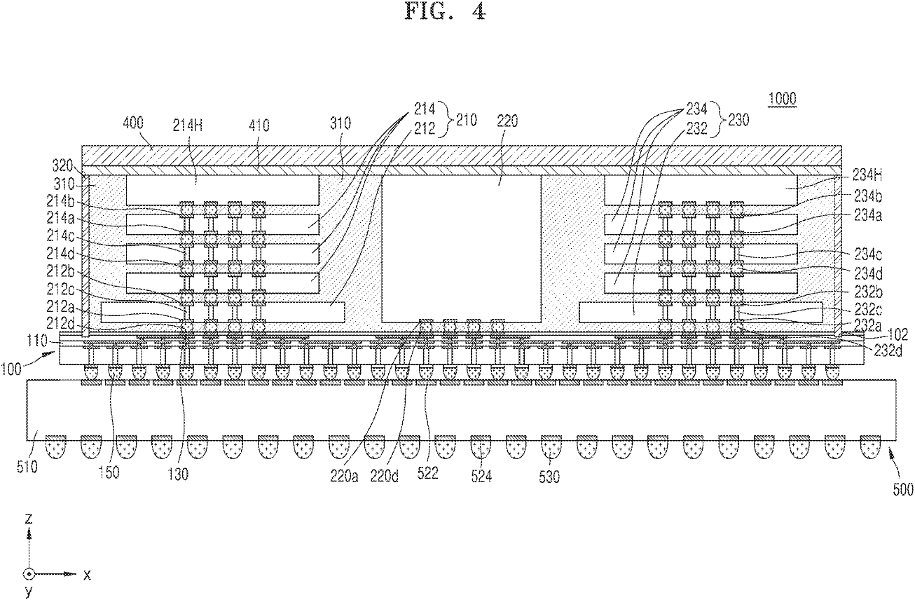

FIG. 4 is a cross-sectional view of a semiconductor package 1000 according to an exemplary embodiment of the inventive concept.

Referring to FIG. 4, the semiconductor package 1000 may include a package base substrate 500, the interposer 100 disposed on the package base substrate 500, the first stacked chip 210 disposed on the interposer 100, the third semiconductor chip 220, a second stacked chip 230, a heat dissipation structure 400, and an adhesive layer 410. Each of the first stacked chip 210, the third semiconductor chip 220, and the second stacked chip 230 may be spaced apart from each other in the first horizontal direction (X direction) on the interposer 100.

Similar to the interposer 100 shown in FIG. 1B, the interposer 100 includes an interposer redistribution layer, the at least one redistribution insulating layer (110 in FIG. 1B), and/or the plurality of redistribution patterns (120 in FIG. 1B), and thus a detailed description thereof is omitted. The third semiconductor chip 220 including a logic semiconductor chip and the first stacked chip 210 and the second stacked chip 230 with the third semiconductor chip 220 interposed therebetween and spaced apart from the third semiconductor chip 220 in the first horizontal direction (X direction) may be disposed on the interposer 100. Each of the first stacked chip 210 and the second stacked chip 230 may be referred to as a memory stack. For example, the semiconductor package 1000 may include a plurality of stacked structures. In the drawings, it is illustrated that two stacked structures are included on one package base substrate 500 by way of example. However, this is exemplary and the number of stacked structures disposed on one package base substrate 500 may be changed in various ways.

The first stacked chip 210 may include the first semiconductor chip 212 and one or more second semiconductor chips 214. As described above, the third semiconductor chip 220 may be disposed between the first stacked chip 210 and the second stacked chip 230. The second stacked chip 230 may include a fourth semiconductor chip 232 and one or more fifth semiconductor chips 234.

The fourth semiconductor chip 232 may include a fourth substrate, a plurality of fourth front connection pads 232a, a plurality of fourth rear connection pads 232b, and a plurality of fourth through electrodes 232c. The fifth semiconductor chip 234 may include a fifth substrate, a plurality of fifth front connection pads 234a, a plurality of fifth rear connection pads 234b, and a plurality of fifth through electrodes 234c.

The fourth substrate and the fifth substrate may be substantially the same as first to third substrates.

The fourth and fifth semiconductor chips 232 and 234 may respectively include fourth and fifth semiconductor devices configured by the plurality of individual devices.

The fourth and fifth semiconductor devices may be formed on active surfaces of the fourth and fifth substrates, and the plurality of fourth and fifth front connection pads 232a and 234a and the plurality of fourth and fifth rear connection pads 232b and 234b may be respectively disposed on the active surfaces and inactive surfaces of the fourth and fifth substrates.

The plurality of fourth through electrodes 232c may vertically penetrate at least a part of the fourth substrate to electrically connect the plurality of fourth front connection pads 232a and the plurality of fourth rear connection pads 232b.

The plurality of fifth through electrodes 234c may vertically penetrate at least a part of the fifth substrate to electrically connect the plurality of fifth front connection pads 234a and the plurality of fourth rear connection pads 232b. The plurality of fifth through electrodes 234c may be electrically connected to the plurality of fourth through electrodes 232c.

The fourth and fifth through electrodes 232c and 234c may be TSVs penetrating silicon of the fourth and fifth semiconductor chips 232 and 234.

In some exemplary embodiments, a fifth semiconductor chip 234H located at the uppermost end among the plurality of fifth semiconductor chips 234 and disposed farthest from the fourth semiconductor chip 232 may omit the fifth rear connection pad 234b and the fifth through electrodes 234c.

For example, the thickness of the fifth semiconductor chip 234H located at the uppermost end may be greater than the thickness of each of the other fifth semiconductor chips 234.

A plurality of fourth chip connection terminals 232d may be attached onto the plurality of fourth front connection pads 232a of the fourth semiconductor chip 232. A plurality of fifth chip connection terminals 234d may be attached onto the plurality of fifth front connection pads 234a of the fifth semiconductor chip 234.

The fourth chip connection terminal 232d may be interposed between the upper surface redistribution pad 130 of the interposer 100 and the plurality of fourth front connection pads 232a of the fourth semiconductor chip 232 to electrically connect the interposer 100 and the fourth semiconductor chip 232.

The fifth chip connection terminal 234d may be disposed between the plurality of fourth rear connection pads 232b of the fourth semiconductor chip 232 and the plurality of fifth front connection pads 234a of the fifth semiconductor chip 234. In addition, the fifth chip connection terminal 234d may be interposed between the plurality of fifth front connection pads 234a of the fifth semiconductor chip 234 and the fifth rear connection pads 244b to electrically connect the fourth semiconductor chip 232 and/or each of the fifth semiconductor chips 234.

As a result, the fourth semiconductor chip 232 and the plurality of fifth semiconductor chips 234 may be electrically connected to each other.

The semiconductor package 1000 may further include the first molding layer 310 and the second molding layer 320 surrounding the first stacked chip 210, the third semiconductor chip 220, and the second stacked chip 230 on the interposer 100. The first molding layer 310 and the second molding layer 320 may be formed of, for example, epoxy mold compound (EMC).

The first molding layer 310 and the second molding layer 320 may directly contact each other. This may be configured such that external stress proceeds along the interface between the first molding layer 310 and the second molding layer 320.

The first molding layer 310 and the second molding layer 320 may be formed of the same material or different materials.

In another exemplary embodiment, the first molding layer 310 may include at least one of a silicon (Si)-based material, a thermosetting material, a thermoplastic material, and a UV treatment material. The second molding layer 320 may include at least one of an epoxy-based material, a thermosetting material, a thermoplastic material, and a UV treatment material.

The heat dissipation structure 400 may be disposed on an upper surface of the second semiconductor chip 214H located on the uppermost end and disposed farthest from the first semiconductor chip 212, the upper surface of the third semiconductor chip 220, and an upper surface of the fifth semiconductor chip 234H located on the uppermost end and disposed farthest from the fourth semiconductor chip 232. That is, a lower surface of the heat dissipation structure 400 may be substantially coplanar with the upper surface of the second semiconductor chip 214H located on the uppermost end and disposed farthest from the first semiconductor chip 212, the upper surface of the third semiconductor chip 220, and the upper surface of the fifth semiconductor chip 234H located on the uppermost end and disposed farthest from the fourth semiconductor chip 232.

According to another exemplary embodiment, the lower surface of the heat dissipation structure 400 may be located at a higher vertical level than the upper surface of the second semiconductor chip 214H located on the uppermost end and disposed farthest from the first semiconductor chip 212, the upper surface of the third semiconductor chip 220, and the upper surface of the fifth semiconductor chip 234H located on the uppermost end and disposed farthest from the fourth semiconductor chip 232.

The thickness of the heat dissipation structure 400 may be greater than the thickness of each of the second semiconductor chip 214 and the fifth semiconductor chip 234. When the thickness of the heat dissipation structure 400 is increased, heat of the semiconductor package 10 may be better dissipated.

The heat dissipation structure 400 may be formed of a semiconductor material. For example, the heat dissipation structure 400 may include silicon (Si). Alternatively, the heat dissipation structure 400 may include a semiconductor element such as germanium (Ge), or a compound semiconductor such as SiC, GaAs, InAs, and InP. For example, the heat dissipation structure 400 may be formed of the same material as a first substrate.

The heat dissipation structure 400 may be formed of a material having higher thermal conductivity than that of each of the first to fifth semiconductor chips 212, 214, 220, 232 and 234. For example, the heat dissipation structure 400 may include copper (Cu). For example, the heat dissipation structure 400 may include electro-plating Cu. Electroplating may be used to perform metal coating on the heat dissipation structure 400 by electrolysis.

The heat dissipation structure 400 may include a plurality of layers. The plurality of layers may be formed of the same single material or may be formed of different materials. The material of the heat dissipation structure 400 is not limited to copper. For example, the heat dissipation structure 400 may be formed of a metal having good thermal conductivity. For example, the heat dissipation structure 400 may include a metal such as nickel (Ni), gold (Au), silver (Ag), aluminum (Al), tungsten (W), titanium (Ti), tantalum (Ta), indium (In), molybdenum (Mo), manganese (Mn), cobalt (Co), tin (Sn), magnesium (Mg), rhenium (Re), beryllium (Be), gallium (Ga), ruthenium (Ru) or an alloy thereof.

According to an exemplary embodiment of the inventive concept, the second semiconductor chip 214H and the heat dissipation structure 400 located at the uppermost end may be adhered to each other by the adhesive layer 410. In addition, the third semiconductor chip 220 and the heat dissipation structure 400 and/or the fifth semiconductor chip 234H and the heat dissipation structure 400 located at the uppermost end may also be adhered to each other by the adhesive layer 410. The adhesive layer 410 may include a thermal interface material (TIM).

According to an exemplary embodiment of the inventive concept, the second molding layer 320 may surround the side surface of the first stacked chip 210, the side surface of the second stacked chip 230, and the side surface of the third semiconductor chip 220. That is, the upper surface of the first stacked chip 210 and the upper surface of the second stacked chip 230, the upper surface of the third semiconductor chip 220, the upper surface of the first molding layer 310, and the lower surface of the heat dissipation structure 400 may be substantially coplanar with the upper surface of the second molding layer 320.

The package base substrate 500 may include a base board layer 510, and a plurality of first upper surface pads 522 and a plurality of first lower surface pads 524 respectively disposed on upper and lower surfaces of the base board layer 510. The package base substrate 500 may include a plurality of first wiring paths (not shown) electrically connecting the plurality of first upper surface pads 522 and the plurality of first lower surface pads 524 through the base board layer 510. In some exemplary embodiments, the package base substrate 500 may be a printed circuit board (PCB). For example, the package base board 500 may be a multi-layer PCB.

The first molding layer 310 and the second molding layer 320 may cover an upper surface of the interposer 100. That is, the first molding layer 310 and the second molding layer 320 may be filled in an empty space between the first stacked chip 210, the second stacked chip 230, and the third semiconductor chip 220.

In FIG. 4, it is illustrated that the semiconductor package 1000 of the inventive concept has a 2.5-dimensional stacked structure by way of example, but the exemplary embodiment of the inventive concept is not limited thereto.

The semiconductor package 1000 may be the lower semiconductor package 1000 or the upper semiconductor package 1000 constituting the package on package (PoP) type semiconductor package 1000.

The semiconductor package 1000 may be a three-dimensional (3D) structure semiconductor package 1000. In the 3D structure semiconductor package 1000, the same or different semiconductor chips may be vertically stacked in multiple layers so that distances between the semiconductor chips may be reduced. The semiconductor chips have respective through electrodes so that a time taken for data transmission with other semiconductor chips may be shortened. In the 3D structure semiconductor package 1000, various types of semiconductor chips 200 may be freely disposed, and thus a data processing speed between the semiconductor chips may be improved.

According to an exemplary embodiment of the inventive concept, the semiconductor package 1000 is a wafer level package (WLP), and may be a fan-out WLP (FOWLP) or a fan-in WLP (FIWLP) in which a package connection terminal or an external connection pad exists outside a semiconductor chip region or only inside the semiconductor chip region.

For example, the semiconductor package 1000 may be a chip-last fan-out semiconductor package in which the interposer 100 or a semiconductor substrate is first formed, and then at least one semiconductor chip is mounted on the interposer 100 or the semiconductor substrate. In another exemplary embodiment, the semiconductor package 1000 may be a chip-first package in which at least one semiconductor chip is mounted on a tape, is surrounded by a molding layer, and then is connected to the interposer 100 or the semiconductor substrate. In some exemplary embodiments, the semiconductor package 1000 may be a fan-out panel level package (FOPLP).

For example, the semiconductor package 1000 may include a plurality of semiconductor chips, and the semiconductor package 1000 may be a system-in package in which a plurality of different types of semiconductor chips are electrically connected to each other and operates as a system.

While the inventive concept has been particularly shown and described with reference to exemplary embodiments thereof, it will be understood that various changes and modifications in form and details may be made therein without departing from the spirit and scope of the following appended claims.

What is claimed is:

1. A semiconductor package comprising:
an interposer;
a first stacked chip comprising a first semiconductor chip disposed on the interposer and one or more second semiconductor chips disposed on the first semiconductor chip;
a first molding layer surrounding the first stacked chip; and
a second molding layer surrounding the first molding layer,
wherein the second molding layer extends from an uppermost surface of the interposer to a trench of the interposer.

2. The semiconductor package of claim 1, wherein the second molding layer covers at least a side surface of the first molding layer.

3. The semiconductor package of claim 1, wherein the second molding layer covers a side surface and an upper surface of the first molding layer.

4. The semiconductor package of claim 2, wherein the second molding layer does not cover an upper surface of the first molding layer.

5. The semiconductor package of claim 1, wherein the first molding layer and the second molding layer are in direct contact with each other.

6. The semiconductor package of claim 1, wherein each of outer surfaces of the second molding layer is substantially coplanar with a side surface of the interposer.

7. The semiconductor package of claim 1, wherein one of outer surfaces of the second molding layer is substantially coplanar with a side surface of the interposer,
wherein remaining outer surfaces of the second molding layer are not aligned with the side surface of the interposer in a vertical direction, and are located inside the interposer in a horizontal direction.

8. The semiconductor package of claim 1, wherein each of outer surfaces of the second molding layer is not aligned with a side surface of the interposer in a vertical direction and is located inside the interposer in a horizontal direction.

9. The semiconductor package of claim 1,
wherein the first semiconductor chip is a buffer chip configured to control the second semiconductor chip, and
wherein the second semiconductor chip is a memory cell chip.

10. The semiconductor package of claim 1, wherein the first molding layer and the second molding layer are of different materials.

11. A semiconductor package comprising:
an interposer;
a first stacked chip comprising a first semiconductor chip disposed on the interposer and one or more second semiconductor chips disposed on the first semiconductor chip;
a third semiconductor chip disposed on the interposer and spaced apart from the first stacked chip in a horizontal direction;
a first molding layer surrounding the first stacked chip and the third semiconductor chip; and
a second molding layer surrounding the first molding layer,
wherein the second molding layer extends from an uppermost surface of the interposer to a trench of the interposer.

12. The semiconductor package of claim 11, wherein a ratio of a height of the trench to a height of the interposer is less than or equal to about 50%.

13. The semiconductor package of claim 11, wherein an upper surface of the first molding layer, an upper surface of the second molding layer, an upper surface of the first stacked chip, and an upper surface of the third semiconductor chip are substantially coplanar.

14. The semiconductor package of claim 11,
wherein the first semiconductor chip is a buffer chip configured to control the second semiconductor chip,
wherein the second semiconductor chip is a memory cell chip, and
wherein the third semiconductor chip is a logic chip.

15. The semiconductor package of claim 11, further comprising: a third molding layer surrounding the second molding layer on the interposer.

16. The semiconductor package of claim 15, wherein a lower surface of the first molding layer, a lower surface of the third molding layer, and an upper surface of the interposer are substantially coplanar.

17. The semiconductor package of claim 15, wherein a lower surface of the first molding layer and a lower surface of the third molding layer are located at different vertical levels.

18. A semiconductor package comprising:
a package base substrate;
an interposer disposed on the package base substrate;
a first stacked chip comprising a first semiconductor chip disposed on the interposer and one or more second semiconductor chips disposed on the first semiconductor chip;
a third semiconductor chip disposed on the interposer and horizontally spaced apart from the first stacked chip;
a second stacked chip disposed on the interposer, spaced apart from the first stacked chip and the third semiconductor chip in a horizontal direction, and comprising a fourth semiconductor chip and one or more fifth semiconductor chips disposed on the fourth semiconductor chip;
a heat dissipation structure disposed on the first stacked chip, the third semiconductor chip, and the second stacked chip;
a first molding layer surrounding a side surface of each of the first stacked chip, the third semiconductor chip, and the second stacked chip; and
a second molding layer surrounding a side surface of the first molding layer,
wherein a lower surface of the heat dissipation structure is coplanar with or at a higher vertical level than an upper surface of the first stacked chip, an upper surface of the third semiconductor chip, and an upper surface of the second stacked chip,
wherein the second molding layer extends from an uppermost surface of the interposer to a trench of the interposer; and
wherein a ratio of a height of the trench to a height of the interposer is less than or equal to 50%.

19. The semiconductor package of claim 18, wherein the height of the trench is less than or equal to about 50 µm.

20. The semiconductor package of claim 18, wherein a width in a first horizontal direction from an inner surface of the second molding layer to an outer surface of the second molding layer is less than or equal to about 100 µm.
